(19) United States
(12) Patent Application Publication
(10) Pub. No.: US 2009/0219087 A1
(43) Pub. Date: Sep. 3, 2009

(54) TRAVELLING WAVE AMPLIFIER

(76) Inventor: Francis Auvray, Montrouge (FR)

Correspondence Address: SCULLY SCOTT MURPHY & PRESSER, PC, 400 GARDEN CITY PLAZA, SUITE 300, GARDEN CITY, NY, 11530, US

(21) Appl. No.: 11/568,034

(22) PCT Filed: Apr. 19, 2005
(86) PCT No.: PCT/IB2005/051264

§ 371 Date: Oct. 18, 2006

(30) Foreign Application Priority Data
Apr. 21, 2004 (EP) 04300215.3

(51) Int. Cl. H03F 3/60; H03F 3/16

(52) U.S. Cl. 330/53

(57) ABSTRACT

A travelling wave amplifier has two inductive transmission lines (12,14) with a plurality of amplifier devices (10) connected between them. At least one of the transmission lines (14) further comprises a plurality of delay elements (50), each delay element being provided in series between a respective pair of inductive elements. The delay elements enable the pulse propagation speeds in the two transmission lines to be matched while leaving freedom in the selection of impedance values to provide input and output impedance matching of the amplifier. In this way, even when the individual amplifier devices (10) have unequal input and output impedances, the amplifier can be configured to provide matched input and output impedances as well as matched propagation speeds.

This invention relates to travelling wave amplifiers.

Travelling wave amplifiers comprise a succession of amplifying devices, each having an input and an output, connected between two inductor chains. Each inductor chain comprises a succession of inductances connected in series with one another.

An input capacitance is associated with the input of each of the amplifying devices and a respective output capacitance is associated with the output of each of the amplifying devices.

The inputs of the amplifying devices are coupled to one inductor chain at the junctions between inductors, and the outputs of the amplifying devices are coupled to the other inductor chain, again at the junctions between inductors. An input transmission line is defined by the first inductor chain and the input capacitances associated with the amplifying devices, and an output transmission line is defined by the second inductor chain and the output capacitances associated with the amplifying devices.

At each frequency in the operating frequency range of the amplifier, for each pair of successive amplifying devices, the phase delays for electromagnetic energy propagating along the input transmission line and along the output transmission line are substantially equal. A wave propagates along each transmission line, and for the correct operation of the amplifier, these waves need to propagate at the same speed.

The concept of a travelling wave (or distributed) amplifier is well known and this amplifier configuration has been used to provide amplification of microwave signals over a broad frequency range, using Field Effect Transistors (FETs) as the amplifying devices. This offers the possibility of integrating the travelling wave amplifier, together with other RF circuitry, onto a single semiconductor substrate.

Ideally, an amplifier is provided with matched input and output impedances. The input and output impedances of the travelling wave amplifier described above is dependent on the input and output capacitance of the individual amplifying devices. In the case of FETs, the input and output capacitances are not easily controlled, and typically the FET design will not result in the travelling wave amplifier having matched input and output impedances. The drain-source (output) capacitance of a FET is generally less than the gate-source (input) capacitance.

For given input and output characteristics of the amplifiers, the inductances in the transmission lines are selected to achieve the required equal wave propagation speeds, and this leaves no scope for also obtaining input and output impedance matching.

The input and output capacitances of the individual amplifiers can be equalised, by introducing additional capacitive elements, but this introduces additional complexity and degrades performance.

There is therefore a need to provide input and output impedance matching for a travelling wave amplifier, whilst leaving design freedom for the individual amplifying devices and maintaining equal propagation speeds in the transmission lines, and with minimum additional complexity to the circuit.

According to the invention, there is provided a travelling wave amplifier comprising:

a first transmission line associated with an input to the amplifier, and comprising a first plurality of inductive elements in series;

a second transmission line associated with an output of the amplifier, and comprising a second plurality of inductive elements in series; and

a plurality of amplifier devices connected between the first and second transmission lines,

wherein at least one of the first and second transmission lines further comprises a plurality of delay elements, each delay element being provided in series between a respective pair of inductive elements.

The delay elements provided in one of the transmission lines enable the pulse propagation speeds in the two transmission lines to be matched while leaving freedom in the selection of impedance values to provide input and output impedance matching of the amplifier. In this way, even when the individual amplifier devices have unequal input and output impedances, the amplifier can be configured to provide matched input and output impedances as well as matched propagation speeds.

Each amplifier device preferably comprises a field effect transistor arrangement, having a gate connected to the first transmission line and a drain connected to the second transmission line. This enables IC integration of the amplifier components. Each field effect transistor arrangement may comprise one or more field effect transistors connected in series between the second transmission line and a common terminal.

The second transmission line, associated with the output, preferably comprises the plurality of delay elements. In particular, the amplifier device outputs connect to the second transmission line, and the lower output capacitance of the FETs gives rise to higher propagation speed in the second transmission line. This higher speed is compensated by the delay elements.

Each delay element may comprise an integrated circuit delay line, integrated into an integrated circuit of the amplifier devices. The delay lines can easily be incorporated into the IC design in known manner, with little or no additional manufacturing complexity or reduction in yield.

Each delay element may have an impedance selected in dependence on the output capacitance of each amplifier device and the inductance of the inductor elements in the second transmission line. The impedance value is selected to provide the input and output impedance matching. However, each delay element has a time delay selected to ensure equal propagation speeds through the first and second transmission lines.

The input 16 is preferably provided to one end of the first transmission line, and the other end of the first transmission line is connected to a common potential through a first terminating resistance. The output is preferably provided from one end of the second transmission line, and the other end of the second transmission line is connected to a common potential through a second terminating resistance. This defines a known configuration.

The impedance of each delay element is preferably equal in magnitude to the resistance of the second terminating resistance.

An example of the invention will now be described in detail with reference to the accompanying drawings, in which:

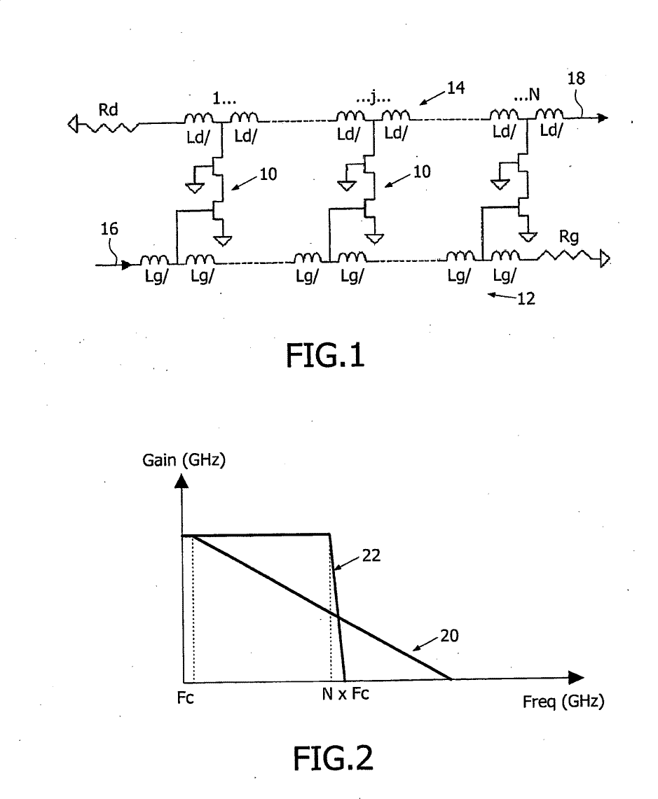

FIG. 1 shows a known travelling wave amplifier;

FIG. 2 shows the benefit of the amplifier of FIG. 1 over a single stage amplifier;

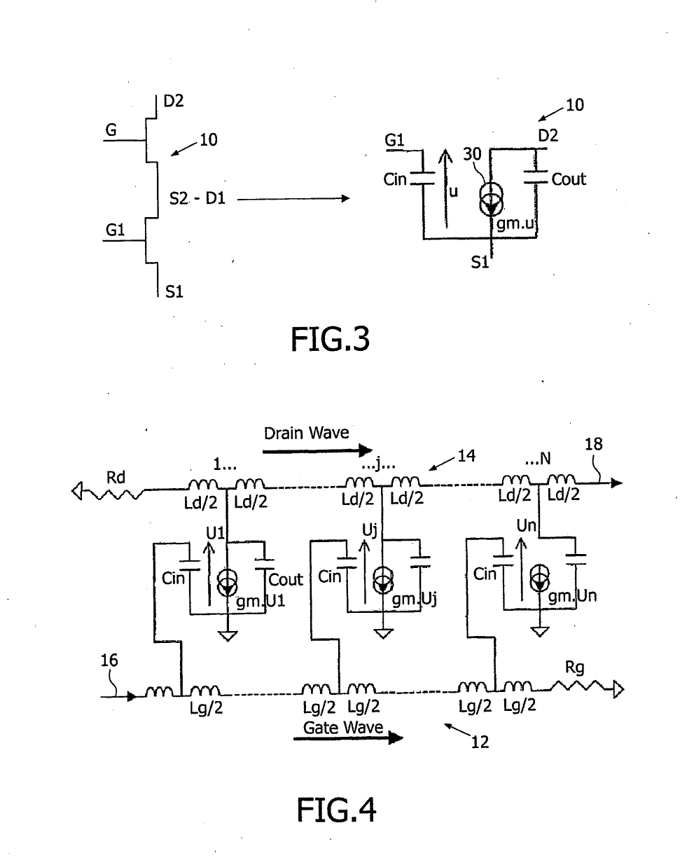

FIG. 3 shows an equivalent circuit of one of the amplifier devices used in the circuit of FIG. 1, for the purposes of analysis;

FIG. 4 shows the circuit of FIG. 1 using the equivalent circuit of FIG. 3 to analyse the behaviour of the circuit of FIG. 1;

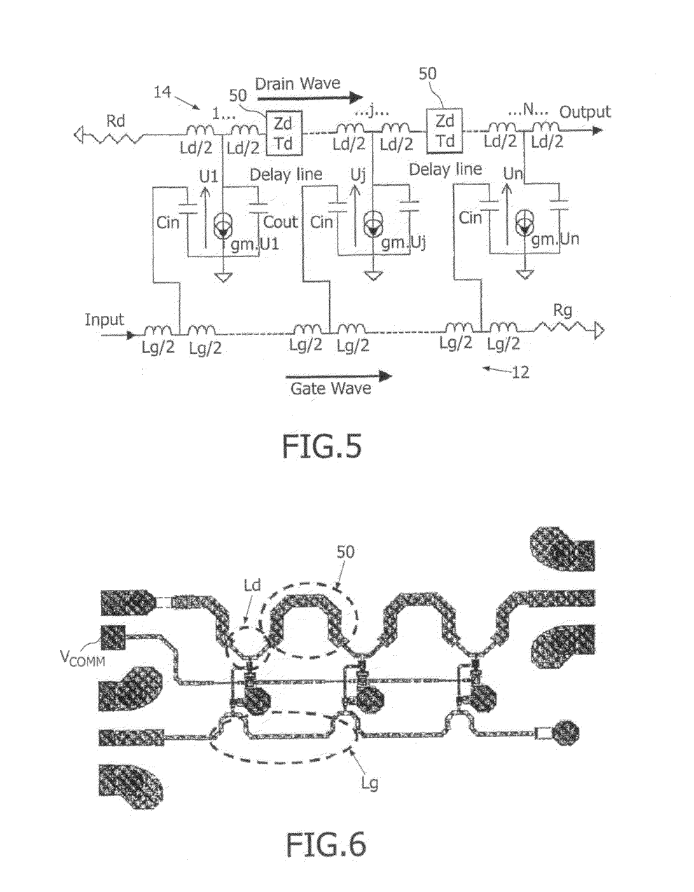

FIG. 5 shows one example of travelling wave amplifier of the invention;

FIG. 6 shows schematically how the invention can be implemented in an integrated circuit; and

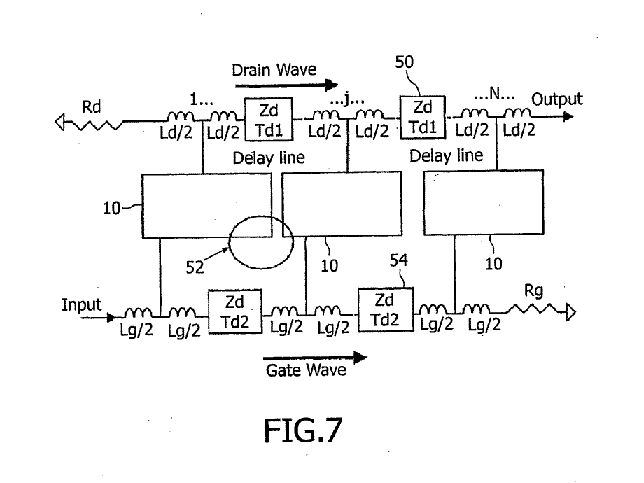

FIG. 7 shows another example of travelling wave amplifier of the invention.

FIG. 1 shows a known travelling wave amplifier, which comprises a plurality of cascode cells 10 provided between a first transmission line 12 and a second transmission line 14.

The first transmission line 12 is associated with an input 16 to the amplifier, and comprises a first plurality of inductive elements in series. The inductive elements between any pair of cascode cells have inductance Lg, whereas the first and last inductive elements have inductance ½ Lg, as shown.

The second transmission line 14 is associated with an output 18 of the amplifier, and comprises a second plurality of inductive elements in series. The inductive elements between any pair of cascode cells have inductance Ld, whereas the first and last inductive elements have inductance ½ Ld, as shown.

The input 16 is provided to one (input) end of the first transmission line 12, and the other (output) end of the first transmission line is connected to a common potential through a first terminating resistance Rg. The output 18 is provided from the output end of the second transmission line 14, and the input end of the second transmission line 14 is connected to a common potential through a second terminating resistance Rd. The terminating resistances prevent reflections along the transmission lines and the common potential is typically ground.

Each amplifier device 10 is shown in this example as two field effect transistors in series, defining a cascode configuration. The gate of one is connected to the first transmission line 12 and the drain of the other is connected to the second transmission line 14.

FIG. 2 shows the benefit of the amplifier of FIG. 1 over a single stage amplifier. Plot 20 shows the gain versus frequency for a single stage amplifier, and plot 22 shows the gain versus frequency for the travelling wave amplifier, with a wider bandwidth than single stage amplifier for the same total gate length.

Before describing the invention, a simplified analysis of the circuit of FIG. 1 is provided. For this purpose, FIG. 3 shows a simplified equivalent circuit of one of the amplifier devices used in the circuit of FIG. 1, for the purposes of analysis.

In FIG. 3, each amplifier device 10 is represented as a voltage-controlled current source 30 with an input (gate-source) capacitance Cin and an output (source-drain) capacitance Cout. This representation ignores the resistances within the amplifier device 10, but this model is sufficient for the analysis to illustrate to the principle of the invention.

FIG. 4 shows the circuit of FIG. 1 using the equivalent circuit of FIG. 3 to analyse the behaviour of the circuit of FIG. 1

Two waves propagate through the transmission lines, and these are shown as “Drain Wave” for the output transmission line 14 and “Gate Wave” for the input transmission line 12.

A voltage impulse is applied at the input 16, and this propagates along the transmission line 12, which comprises the inductors Lg and the input capacitances Cin, towards the terminating resistor Rg.

Each time this impulse reaches one of the transistor inputs of the amplifier device 10, it launches a current pulse to the drain of the output transistor of the amplifier device 10. This impulse propagates along the output transmission line 14, which comprises the inductors Ld, and the output capacitances Cout, towards the output 18.

These two waves must have the same velocity for correct signal amplification.

There are two conflicting desirable circuit parameters in the circuit of FIG. 1. One is matching of the input and output impedance, and the other is the velocity matching.

### Impedance Matching Conditions:

The input and output impedances are given by:

(Lg/Cin)^{-0.5}=Rg=Rsource

(Ld/Cout)^{-0.5}=Rd=Rload

For impedance matching, Rg=Rd is required. Hence:

Lg/Cin=Ld/Cout (1)

### Velocity Matching Conditions:

The propagation times along the two transmission lines are given by:

Tg=(Lg×Cin)^{-0.5}

Td=(Ld×Cout)^{-0.5}

For velocity matching, Tg=Td is required. Hence:

Lg×Cin=Ld×Cout (2)

The two conditions above are contradictory, and can only be satisfied if Cin=Cout and Ld=Lg. However, in practical implementations of the amplifiers 10, Cin is different to Cout and a tradeoff is necessary. Typically, Cin is higher than Cout.

The impedance matching condition (1) in this case gives rise to impedance values Ld<Lg. This in turn gives rise to the relation Ld*Cout<Lg*Cin.

Thus, setting the circuit of FIG. 1 to an impedance matching condition gives rise to a mismatch in propagation velocities in the two transmission lines. In particular, the velocity of the drain wave is greater than the velocity of the gate wave.

In accordance with the invention, at least one of the first and second transmission lines further comprises a plurality of delay elements, each delay element being provided in series between a respective pair of inductive elements. In the case described above, where the impedance matching gives rise to a greater velocity drain wave, the output transmission line 14 through which the drain wave propagates is provided with the plurality of delay elements.

This arrangement is shown in FIG. 5, and delay elements in the form of delay lines are shown as elements 50.

The delay elements 50 enable the pulse propagation speeds in the two transmission lines to be matched while leaving freedom in the selection of impedance value to provide input and output impedance matching of the amplifier. In this way, even when the individual amplifier devices 10 have unequal input and output impedances, the amplifier can be configured to provide matched input and output impedance as well as matched propagation speeds.

The delay line impedance is matched to the terminating resistor Rd and is selected to satisfy the impedance matching condition:

Zd=Rd=(Ld/Cout)^{-0.5} (3)

Each delay element impedance is thus selected in dependence on the output capacitance of each amplifier device 10 and the inductance of the inductor elements in the second transmission line.

The delay line time delay is selected to provide the matched propagation speed:

Td=(Lg*Cin)^{-0.5}−(Ld*Cout)^{-0.5} (4)

For a given delay line design with desired impedance, this time delay is varied by selecting the length of the delay line (generally the time delay varies with the square of the delay line length).

Each delay element may comprise an integrated circuit delay line, integrated into an integrated circuit of the amplifier devices. The delay lines can easily be incorporated into the IC design in known manner, with little or no additional manufacturing complexity or reduction in yield.

FIG. 6 shows schematically how the invention can be implemented in an integrated circuit. The delay lines 50 are shown as track portions having the desired length, width and materials to provide the desired impedance and time delay. For example, the impedance may be selected as 50 Ohms.

In the example above, only the output transmission line is provided with delay elements. However, when the operation frequency is very high, for example around 150 GHz, the required dimensions of the inductors become less than the width of the amplifier circuit 10. FIG. 7 shows an arrangement in which both transmission lines 12,14 are provide with delay elements. The use of delay elements in both transmission lines can be used to stretch the circuit, and prevent physical overlap of the amplifier circuits, at region 52. As shown in FIG. 7, the output transmission line 14 has delay elements of delay Td1 and the input transmission line 12 has delay elements of delay Td2, and these delay elements all have the same impedance.

The required effective time delay is given by:

Td1−Td2=(Lg*Cin)^{-0.5}−(Ld*Cout)^{-0.5} (5)

The values of Td1 and Td2 can thus be selected accordingly.

The invention can be applied to all known uses of travelling wave amplifier, essentially when wide band amplification is required. Travelling wave amplifiers are used in broadcast transmitters and receivers, cable networks, space communications and many other applications.

The invention can be implemented in an MMIC (monolithic microwave IC), and is suitable for electrical signal processing at high frequencies, for example corresponding to the high bit rates used in optical communications systems, for example 10 GB/s-40 GB/s In the example above, the amplifier devices are shown as twin TFT cascode cells. However, a single TFT may function as the amplifying device.

The invention is also applicable to vacuum tube travelling wave amplifiers, used for very high power amplifications. Other designs for the amplifying device are also possible.

Only two detailed examples have been given above, but it will be apparent to those skilled in the art that other circuit configurations for travelling wave amplifiers are possible. The invention is applicable to any such circuit configuration in which two transmission lines are provided. The use of delay elements in accordance with the invention enables the propagation speeds to be matched using the delay elements, so that design freedom is kept for other circuit parameters, for example to provide impedance matching. This design freedom may, however, be used for other purposes, and the invention is not limited to an amplifier with matched input and output impedance.

The invention particularly enables an improved gain across the required bandwidth with improved impedance matching. The invention can also improve the stability factor of the amplifier.

Various other modifications will be apparent to those skilled in the art.

1. A travelling wave amplifier comprising:
a first transmission line (12) associated with an input to the amplifier, and comprising a first plurality of inductive elements (Lg) in series;
a second transmission line (14) associated with an output of the amplifier, and comprising a second plurality of inductive elements (Ld) in series; and
a plurality of amplifier devices (10) connected between the first and second transmission lines,
wherein at least one of the first and second transmission lines (12,14) further comprises a plurality of delay elements (50), each delay element being provided in series between a respective pair of inductive elements.

2. An amplifier as claimed in claim 1, wherein each amplifier device (10) comprises a field effect transistor arrangement, having a gate connected to the first transmission line (12) and a drain connected to the second transmission line (14).

3. An amplifier as claimed in claim 2, wherein each field effect transistor arrangement comprises one or more field effect transistors connected in series between the second transmission line and a common terminal.

4. An amplifier as claimed in claim 1, wherein the second transmission line (14) comprises the plurality of delay elements (50).

5. An amplifier as claimed in claim 1, wherein each delay element (50) comprises an integrated circuit delay line, integrated into an integrated circuit of the amplifier devices (10).

6. An amplifier as claimed in claim 1, wherein each delay element (50) has an impedance (Zd) selected in dependence on the output capacitance of each amplifier device (10) and the inductance of the inductor elements (Ld) in the second transmission line (14).

7. An amplifier as claimed in claim 1, wherein each delay element (50) has a time delay (Td) selected to ensure equal propagation speeds through the first and second transmission lines (12,14).

8. An amplifier as claimed in claim 1, wherein the input is provided to one end of the first transmission line (12), and the other end of the first transmission line is connected to a common potential through a first terminating resistance (Rg).

9. An amplifier as claimed in claim 1, wherein the output is provided from one end of the second transmission line (14), and the other end of the second transmission line is connected to a common potential through a second terminating resistance (Rd).

10. An amplifier as claimed in claim 9, wherein the impedance (Zd) of each delay element is equal in magnitude to the resistance of the second terminating resistance (Rd).

11. An amplifier as claimed in claim 1, wherein the propagation speed through the first and second transmission lines (12,14) is substantially equal and the input and output impedance of the amplifier is substantially equal.

12. An amplifier as claimed in claim 11, wherein an input and output capacitance of each amplifier device is unequal.

13. An amplifier as claimed in claim 1, wherein the first and second transmission lines (12,14) each comprises a plurality of delay elements (54,50) of different delay values (Td2,Td1).

14. An amplifier as claimed in claim 1 comprising a microwave RF amplifier.
